(19) United States
(12) Patent Application Publication
(10) Pub. No.: US 2025/0323196 A1
(43) Pub. Date: Oct. 16, 2025

(54) SEMICONDUCTOR PACKAGE AND METHOD OF MANUFACTURING THE SAME

(71) Applicant: SAMSUNG ELECTRONICS CO., LTD., Suwon-si (KR)

(72) Inventors: Kyungdon MUN, Suwon-si (KR); Hyeonjeong HWANG, Suwon-si (KR)

(73) Assignee: SAMSUNG ELECTRONICS CO., LTD., Suwon-si (KR)

(21) Appl. No.: 18/986,086

(22) Filed: Dec. 18, 2024

(30) Foreign Application Priority Data
Jan. 15, 2024 (KR) 10-2024-0006303

(51) Int. Cl. H01L 23/00; H01L 23/31; H01L 23/538; H01L 25/16; H10B 80/00

(52) U.S. Cl. CPC H01L 24/08; H01L 23/5385; H01L 24/16; H01L 24/32; H01L 24/73; H01L 25/16; H01L 23/3135; H01L 2224/08238; H01L 2224/16145; H01L 2224/16227; H01L 2224/32145; H01L 2224/32225; H01L 2224/73204; H10B 80/00

(57) ABSTRACT

A semiconductor package includes: an interposer substrate in which a bridge chip is mounted; a first semiconductor device on the interposer substrate, the first semiconductor device comprising a first semiconductor chip and a plurality of second semiconductor chips stacked in a first direction; and a second semiconductor device spaced apart from the first semiconductor device in a second direction, where an interposer bonding pad is on a face of the bridge chip, a first chip bonding pad that overlaps at least part of the interposer bonding pad in the first direction is on a face of the first semiconductor chip, and a second chip bonding pad that overlaps part of a remaining interposer bonding pad in the first direction is on a face of the second semiconductor device, and where the interposer bonding pad is metal-metal hybrid bonded to the first chip bonding pad and the second chip bonding pad.

### CROSS-REFERENCE TO RELATED APPLICATION

This application is based on and claims priority under 35 U.S.C. § 119 to Korean Patent Application No. 10-2024-0006303, filed on Jan. 15, 2024, in the Korean Intellectual Property Office, the disclosure of which is incorporated by reference herein in its entirety.

### BACKGROUND

### 1. Field

The technical idea of the embodiments of the present disclosure relate to a semiconductor package and a manufacturing method thereof. More specifically, the technical idea of the embodiments of the present disclosure relate to a semiconductor package including a stacked semiconductor chip and a method of manufacturing the same.

### 2. Description of Related Art

In accordance with the development of the electronics industry and consumer demands, electronic devices are becoming miniaturized and lightweight. With the miniaturization and reduction in weight of the electronic devices, semiconductor packages included in the electronic devices are also becoming miniaturized and lightweight, where the semiconductor packages are also required to be highly integrated and have high speed. However, current semiconductor packages are unable to meet integration and speed requirements with miniaturized and lightweight components. In response to these demands, semiconductor packages including stacked semiconductor chips are being developed.

### SUMMARY

The task to be solved by the technical idea of the embodiments of the present disclosure is to provide a semiconductor package that may be manufactured inexpensively and have improved performance.

According to an aspect of the disclosure, a semiconductor package comprises: an interposer substrate in which a bridge chip is mounted; a first semiconductor device on the interposer substrate, the first semiconductor device comprising a first semiconductor chip and a plurality of second semiconductor chips that are sequentially stacked in a first direction; and a second semiconductor device spaced apart from the first semiconductor device in a second direction perpendicular to the first direction, in which an interposer bonding pad is on a face of the bridge chip, a first chip bonding pad that overlaps at least part of the interposer bonding pad in the first direction is on a face of the first semiconductor chip, and a second chip bonding pad that overlaps part of a remaining interposer bonding pad in the first direction except the part of the interposer bonding pad that overlaps the first chip bonding pad in the first direction is on a face of the second semiconductor device, and in which the interposer bonding pad is metal-metal hybrid bonded to the first chip bonding pad and the second chip bonding pad.

According to an aspect of the disclosure, a semiconductor package comprises: an interposer substrate comprising a circuit structure; a first semiconductor device on the interposer substrate, the first semiconductor device comprising a first semiconductor chip and a plurality of second semiconductor chips that are sequentially stacked in a first direction; and a second semiconductor device spaced apart from the first semiconductor device in a second direction perpendicular to the first direction, in which an interposer bonding pad is on a portion of a face of the interposer substrate that overlaps the circuit structure in the first direction, a first chip bonding pad that overlaps at least part of the interposer bonding pad in the first direction is on a face of the first semiconductor chip, and a second chip bonding pad that overlaps part of a remaining interposer bonding pad in the first direction except the part of the interposer bonding pad that overlaps the first chip bonding pad in the first direction is on a face of the second semiconductor device, and in which the interposer bonding pad is metal-metal hybrid bonded to the first chip bonding pad and the second chip bonding pad.

According to an aspect of the disclosure, a semiconductor package comprises: a package substrate; an interposer substrate on the package substrate and in which a bridge chip is mounted; a first semiconductor device on the interposer substrate, the first semiconductor device comprising a first semiconductor chip and a plurality of second semiconductor chips that are sequentially stacked in a first direction; and a second semiconductor device spaced apart from the first semiconductor circuit in a second direction perpendicular to the first direction, in which an interposer bonding pad is on a face of the bridge chip, a first chip bonding pad that overlaps at least part of the interposer bonding pad in the first direction is on a face of the first semiconductor chip, and a second chip bonding pad that overlaps part of a remaining interposer bonding pad in the first direction except the part of the interposer bonding pad that overlaps the first chip bonding pad in the first direction is on a face of the second semiconductor device, and the interposer bonding pad is metal-metal hybrid bonded to the first chip bonding pad and the second chip bonding pad.

### BRIEF DESCRIPTION OF DRAWINGS

Embodiments will be more clearly understood from the following detailed description taken in conjunction with the accompanying drawings in which:

FIG. 1 is a plan view illustrating a semiconductor package according to embodiments;

FIG. 2 is a cross-sectional view taken along line A-A′ of FIG. 1 according to embodiments;

FIG. 3 is a cross-sectional view illustrating a semiconductor package according to embodiments;

FIG. 4 is a cross-sectional view illustrating a semiconductor package according to embodiments;

FIGS. 5A, 5B, and 5C are cross-sectional views illustrating a method of manufacturing a semiconductor package, according to embodiments;

FIGS. 6A and 6B are cross-sectional views illustrating a method of manufacturing a semiconductor package, according to embodiments; and

FIGS. 7A and 7B are cross-sectional views illustrating a method of manufacturing a semiconductor package, according to embodiments.

### DETAILED DESCRIPTION OF EMBODIMENTS

Embodiments of the technical idea of the embodiments of the present disclosure will be described below in detail with reference to the attached drawings. The same reference numerals are used for the same components in the drawings, and a repeated description thereof is omitted.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

A layer may be described as having an upper surface and a lower surface. As understood by one of ordinary skill in the art, the surfaces of a layer may also be described as first and second surfaces, where a first surface may be one of the upper surface and the lower surface of the layer, and the second surface may be the other of the upper surface and the lower surface of the layer.

The specification uses the terms of degree including “substantially” or “about.” In one or more examples, when specifying that a parameter X may be substantially the same as parameter Y, the term “substantially” may be understood as X being within 10% of Y. In one or more examples, when specifying that a parameter is about X, the term “about” may be understood as being within 10% of X.

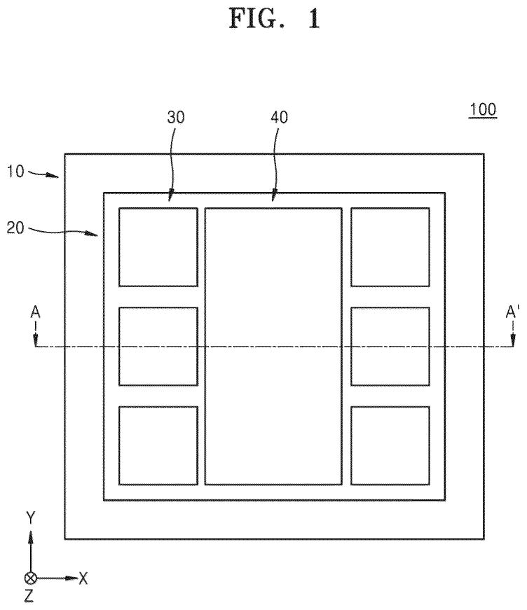

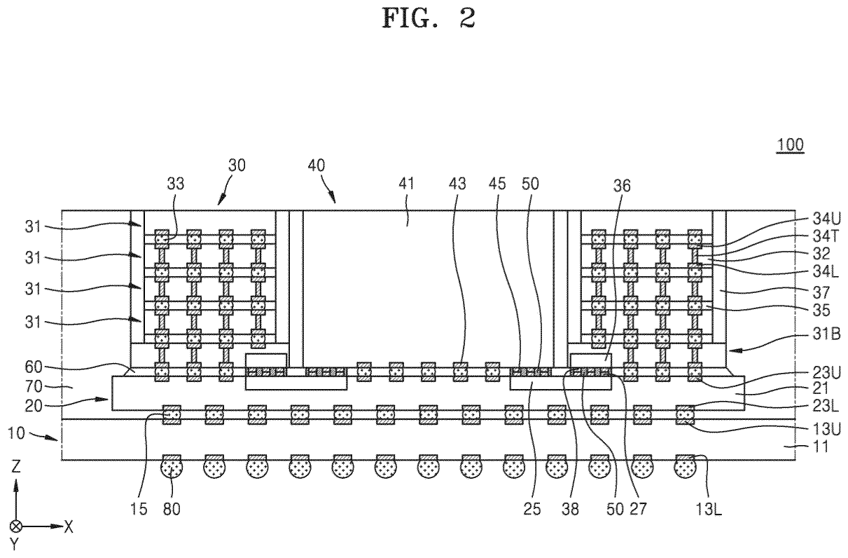

FIG. 1 is a plan view illustrating a semiconductor package 100 according to embodiments. FIG. 2 is a cross-sectional view taken along line A-A′ of FIG. 1.

Referring to FIGS. 1 and 2, the semiconductor package 100 may include a package substrate 10, an interposer substrate 20, a plurality of first semiconductor devices 30, and a second semiconductor device 40. In one or more examples, an interposer substrate may be a thin substrate that sits between two or more chips or dies, allowing them to communicate and work together. An interposer substrate may provide routing for signals, power distribution, and even thermal management. An interposer substrate may be used when integrating different technologies or combining multiple chips into a single package.

The package substrate 10 may include a printed circuit board. For example, the package substrate 10 may include a multi-layer printed circuit board.

In one or more examples, the package substrate 10 may include a substrate base 11, and an upper pad 13U and a lower pad 13L that are formed on an upper face and a lower face of the substrate base 11, respectively. The substrate base 11 may be comprised of a single base layer or may be comprised of a structure in which a plurality of base layers are stacked. The substrate base 11 may be made of at least one material selected from, for example, phenol resin, epoxy resin, and polyimide. The substrate base 11 may include at least one material selected from, for example, frame retardant 4 (FR4), tetrafunctional epoxy, polyphenylene ether, epoxy/polyphenylene oxide, bismaleimide triazine (BT), thermount, cyanate ester, polyimide, and liquid crystal polymer. The upper pad 13U and the lower pad 13L may be exposed from solder resist layers covering the upper face and the lower face of the substrate base 11, respectively. In one or more examples, the upper pad 13U may be aligned with the lower pad 13L. In one or examples, the substrate base 11 may include a plurality of upper pads 13U and a plurality of lower pads 13L, where each upper pad 13U is aligned with a corresponding lower pad 13L.

In one or more examples, an external connection terminal 80 may be disposed on the lower pad 13L of the package substrate 10. The external connection terminal 80 may include, for example, a solder ball or a bump. The external connection terminal 80 may electrically connect the semiconductor package 100 to an external device.

In one or more examples, the interposer substrate 20 may be disposed on the package substrate 10. The interposer substrate 20 may include a substrate base 21, and an upper pad 23U and a lower pad 23L that are formed on an upper face and a lower face of the substrate base 21, respectively. In one or more embodiments, the substrate base 21 may include a silicon wafer or a glass substrate. In other embodiments, the substrate base 21 may be made of at least one material selected from phenol resin, epoxy resin, and polyimide. The substrate base 21 may include at least one material selected from, for example, frame retardant 4 (FR4), tetrafunctional epoxy, polyphenylene ether, epoxy/polyphenylene oxide, bismaleimide triazine (BT), thermount, cyanate ester, polyimide, and liquid crystal polymer.

A bridge chip 25 may be mounted in the substrate base 21. In one or more embodiments, the bridge chip 25 may include a memory controller and an input/output circuit. One or more interposer bonding pads 27 may be disposed on an upper face of the bridge chip 25. The bridge chip 25 may be electrically connected to a first semiconductor device 30 and a second semiconductor device 40 through one or more interposer bonding pads 27. The interposer bonding pad 27 may include copper (Cu), for example. In one or more embodiments, a pitch of each of a plurality of interposer bonding pads 27 may be about 1 nm to about 9 nm. For example, a pitch of each interposer bonding pad 27 that overlaps a first chip bonding pad 38 included in the first semiconductor device 30 in a vertical direction (Z direction) may be about 5 nm. For example, a pitch of each interposer bonding pad 27 that overlaps a second chip bonding pad 45 included in the second semiconductor device 40 in the vertical direction (Z direction) may also be about 5 nm.

An internal wire may be formed on an upper face and/or a lower face of the substrate base 21. The internal wire may be within the substrate base 21. In one or examples, through vias electrically connecting the upper pad 23U to the lower pad 23L may be formed within the substrate base 21. The interposer substrate 20 may be mounted on the package substrate 10 by a connection terminal 15. The connection terminal 15 may include, for example, a solder ball or a bump.

In one or more examples, the plurality of first semiconductor devices 30 and the second semiconductor device 40 may be disposed on the interposer substrate 20. On the interposer substrate 20, the plurality of first semiconductor devices 30 may be arranged to face each other horizontally with the second semiconductor device 40 located therebetween. In FIG. 1, it is illustrated that three pairs of first semiconductor devices 30 are arranged to face each other horizontally with the second semiconductor device 40 located therebetween. However, the embodiments of the present disclosure are not limited thereto, and one or more pairs of first semiconductor devices 30 may be also arranged to face each other horizontally with the second semiconductor device 40 located therebetween.

Referring back to FIG. 2, the first semiconductor device 30 may include a first semiconductor chip 31B and a plurality of second semiconductor chips 31. For example, the first semiconductor chip 31B may include a buffer chip for controlling the plurality of second semiconductor chips 31. For example, the plurality of second semiconductor chips 31 may each include a high bandwidth memory (HBM) dynamic random access memory (DRAM) chip, and the first semiconductor chip 31B may include a buffer chip for controlling the plurality of second semiconductor chips 31, for example, HBM DRAM chips. For example, the first semiconductor chip 31B may include a serial-parallel conversion circuit, a test logic circuit such as design for test (DFT), Joint Test Action Group (JTAG), and memory built-in self-test (MBIST), and a signal interface circuit such as physical layer (PHY).

In one or more examples, the first semiconductor chip 31B may include a semiconductor substrate 32, a plurality of through vias 34T, a plurality of upper pads 34U, a plurality of lower pads 34L, an input/output circuit 36, and a plurality of first chip bonding pads 38.

The semiconductor substrate 32 may include, for example, a semiconductor element such as silicon (Si), germanium (Ge), etc., and at least one compound semiconductor selected from silicon germanium (SiGe), silicon carbon (SiC), gallium arsenic (GaAs), indium arsenic (InAs), and indium phosphorous (InP). The semiconductor substrate 32 may include a conductive region, for example, a well doped with impurities, or a structure doped with impurities. The semiconductor substrate 32 may have various device isolation structures, such as a shallow trench isolation (STI) structure.

In one or more examples, the semiconductor substrate 32 may have an active surface and an inactive surface opposite to the active surface. A plurality of various types of individual devices may be formed on the active surface of the semiconductor substrate 32. The plurality of individual devices may include, for example, a metal-oxide-semiconductor field effect transistor (MOSFET) such as a complementary metal-insulator-semiconductor (CMOS) transistor, a system large scale integration (LSI), an image sensor such as a CMOS imaging sensor (CIS) and the like, a micro-electro-mechanical system (MEMS), an active element, a passive element, etc. The plurality of individual devices may be electrically connected to the conductive region of the semiconductor substrate 32. The plurality of individual devices may be each electrically insulated from other neighboring individual devices by an insulating layer.

In one or more examples, the semiconductor substrate 32 may further include a wiring layer disposed on the active surface. The wiring layer may be electrically connected to the plurality of through vias 34T. For example, the wiring layer may include a front-end-of-line (FEOL) layer or a back-end-of-line (BEOL) layer, but the embodiments of the present disclosure are not limited thereto.

The plurality of through vias 34T may penetrate the semiconductor substrate 32 and extend in the vertical direction (Z direction). The plurality of through vias 34T may be each horizontally spaced apart from each other. The plurality of through vias 34T may be equally spaced apart, or spaced apart from each other with varying difference. The through via 34T may electrically connect the lower pad 34L to part of the upper pad 34U that overlaps the lower pad 34L in the vertical direction (Z direction) and may electrically connect the first chip bonding pad 38 to part of the remaining upper pad 34U that overlaps the first chip bonding pad 38 in the vertical direction (Z direction).

In one or more examples, the plurality of upper pads 34U may be disposed on an upper face of the semiconductor substrate 32, and the plurality of lower pads 34L and the plurality of first chip bonding pads 38 may be disposed on a lower face of the semiconductor substrate 32. Some of the plurality of upper pads 34U may overlap the plurality of lower pads 34L in the vertical direction (Z direction), respectively, and some of the remaining plurality of upper pads 34U may overlap the plurality of first chip bonding pads 38 in the vertical direction (Z direction), respectively. The first chip bonding pad 38 may overlap, in the vertical direction (Z direction), the bridge chip 25 arranged in the interposer substrate 20, and the lower pad 34L may not overlap the bridge chip 25 in the vertical direction (Z direction). The upper pad 34U, the lower pad 34L, and the first chip bonding pad 38 may each include copper (Cu).

In one or more examples, each of a plurality of first connection terminals 33 may be disposed on a lower face of each of the plurality of lower pads 34L. For example, each of the plurality of first connection terminals 33 may include a solder ball or a solder bump. Each of the plurality of first connection terminals 33 may include a solder material. The solder material may include, for example, tin (Sn), indium (In), bismuth (Bi), antimony (Sb), copper (Cu), silver (Ag), zinc (Zn), lead (Pb) and/or alloys thereof. The first semiconductor chip 31B may be electrically connected to the interposer substrate 20 through the plurality of first connection terminals 33. As illustrated in FIG. 2, the each connection terminal 33 may connect a bonding pad in the upper face of the interposer substrate 20 with a bonding pad on the lower face of the first semiconductor chip 31B.

In one or more examples, the plurality of first chip bonding pads 38 may be electrically connected to the input/output circuit 36 within the first semiconductor chip 31B. The plurality of first chip bonding pads 38 may overlap, in the vertical direction (Z direction), at least a portion of the interposer bonding pad 27 disposed on the upper face of the bridge chip 25. The plurality of first chip bonding pads 38 may be metal-metal hybrid bonded to at least a portion of the interposer bonding pad 27 that overlaps the plurality of first chip bonding pads 38 in the vertical direction (Z direction) and thus, the input/output circuit 36 within the first semiconductor chip 31B may be electrically connected to the bridge chip 25. In one or more examples, a metal-metal hybrid bonding process may comprise forming a bond between two metals by fusing embedded metal pads in a bond interface. This bonding technique advantageously enables heterogeneous integration to connect two components of two different functions and sizes.

In one or more examples, the plurality of second semiconductor chips 31 may be stacked on the first semiconductor chip 31B. In one or more embodiments, each of the plurality of second semiconductor chips 31 may include a volatile memory semiconductor chip, such as DRAM or static random access memory (SRAM), or may include a non-volatile memory chip, such as phase-change random access memory (PRAM), magnetoresistive random access memory (MRAM), ferroelectric random access memory (FeRAM), a resistive random access memory (ReRAM), or any other suitable memory structure known to one of ordinary skill in the art. For example, each of the plurality of second semiconductor chips 31 may include an HBM DRAM chip constituting an HBM.

In FIG. 2, it is illustrated that the first semiconductor device 30 includes four second semiconductor chips 31 stacked in the vertical direction (Z direction), but the embodiments of the present disclosure are not limited thereto. For example, the first semiconductor device 30 may also include a multiple of 4, for example, 8 or 16 second semiconductor chips 31, or any other suitable number of chips.

In one or more examples, the second semiconductor chip 31 located at the top of the plurality of second semiconductor chips 31 may include a semiconductor substrate 32 and a plurality of lower pads 34L, and each of the plurality of second semiconductor chips 31 other than the second semiconductor chip 31 located at the top may include the semiconductor substrate 32, a plurality of through vias 34T, a plurality of upper pads 34U, and the plurality of lower pads 34L. That is, unlike other second semiconductor chips 31 in a stack, the second semiconductor chip 31 located at the top of the stack (e.g., upper most chip) may not include the plurality of through vias 34T and the plurality of upper pads 34U.

In one or more examples, the semiconductor substrate 32, the plurality of through vias 34T, the plurality of upper pads 34U, and the plurality of lower pads 34L that constitute each of the plurality of second semiconductor chips 31 may have substantially the same or similar structure to the semiconductor substrate 32, the plurality of through vias 34T, the plurality of upper pads 34U, and the plurality of lower pads 34L that constitute the first semiconductor chip 31B.

In one or more examples, the plurality of first connection terminals 33 may be located between the plurality of second semiconductor chips 31, respectively. The plurality of first connection terminals 33 may be arranged to overlap each of the upper pad 34U and the lower pad 34L of each of the plurality of second semiconductor chips 31 in the vertical direction (Z direction). In this regard, each first connection terminal 33 is aligned with a respective upper pad 34U and lower pad 34L. The plurality of second semiconductor chips 31 may be electrically connected to each other by the plurality of first connection terminals 33, respectively. The plurality of first connection terminals 33 respectively located between the plurality of second semiconductor chips 31 may be surrounded by an insulating layer 35.

In one or more examples, side faces of each of the plurality of second semiconductor chips 31 may be surrounded by a first molding layer 37. The first molding layer 37 may include, for example, an epoxy molding compound (EMC). In one or more embodiments, an upper face of the first molding layer 37 may be at the same vertical level as an upper face of the second semiconductor chip 31 located at the top. For example, the upper face of the first molding layer 37 may be substantially planar with the upper face with the upper most second semiconductor chip 31. In other embodiments, the upper face of the first molding layer 37 may be at a different level than the upper face of the uppermost second semiconductor chip 31. For example, the upper face of the first molding layer 37 may be lower or higher than the upper face of the uppermost second semiconductor chip 31.

In one or more examples, the second semiconductor device 40 may be disposed on the interposer substrate 20 and be horizontally spaced apart from the plurality of first semiconductor devices 30. The second semiconductor device 40 may include, for example, a processor unit. For example, the second semiconductor device 40 may include a micro-processor unit (MPU), a graphics processing unit (GPU), a central processing unit (CPU), an application processor (AP), or any other suitable processing structure known to one of ordinary skill in the art. In one or more embodiments, the second semiconductor device 40 may not include a memory controller and an input/output circuit. The memory controller and the input/output circuit may be included in the bridge chip 25 arranged in the interposer substrate 20 as described above.

In one or more examples, the second semiconductor device 40 may include a second semiconductor substrate 41, a second chip pad 43, and a second chip bonding pad 45.

The second semiconductor substrate 41 may include, for example, a semiconductor element such as silicon (Si), germanium (Ge), etc., and at least one compound semiconductor selected from silicon germanium (SiGe), silicon carbon (SiC), gallium arsenic (GaAs), indium arsenic (InAs), and indium phosphorous (InP). The second semiconductor substrate 41 may include a conductive region, for example, a well doped with impurities, or a structure doped with impurities. The second semiconductor substrate 41 may have various device isolation structures, such as a shallow trench isolation (STI) structure.

In one or more examples, the second semiconductor substrate 41 may include an active surface and an inactive surface opposite to the active surface. A semiconductor device including a plurality of various types of individual devices may be formed on the active surface of the second semiconductor substrate 41. The plurality of individual devices may include various microelectronic devices, for example, a MOSFET such as a CMOS transistor, etc., system LSI, an image sensor such as a CMOS imaging sensor (CIS), etc., a MEMS, an active device, a passive device, etc. The plurality of individual devices may be electrically connected to the conductive region of the second semiconductor substrate 41. The semiconductor device may further include a conductive wire or a conductive plug that electrically connects at least two of the plurality of individual devices, or the plurality of individual devices, to the conductive region of the second semiconductor substrate 41. In one or more examples, each of the plurality of individual devices may be electrically insulated from other neighboring individual devices by an insulating film.

In one or more examples, a plurality of second chip pads 43 and a plurality of second chip bonding pads 45 may be disposed on the lower face of the second semiconductor substrate 41. The plurality of second chip pads 43 may overlap an upper pad 23U of the interposer substrate 20 in the vertical direction (Z direction), and the plurality of second chip bonding pads 45 may overlap the interposer bonding pad 27 of the bridge chip 25 in the vertical direction (Z direction). The second semiconductor device 40 may be electrically connected to the interposer substrate 20 by the first connection terminal 33 located between the second chip pad 43 and the upper pad 23U. Each of the plurality of second chip bonding pads 45 may be metal-metal hybrid bonded to at least a portion of the interposer bonding pad 27 that overlaps the plurality of second chip bonding pads 45 in the vertical direction (Z direction) and thus, the second semiconductor device 40 may be electrically connected to the bridge chip 25.

In one or more examples, a bonding insulating layer 50 may surround the first chip bonding pads 38 and one or more of the interposer bonding pads 27 metal-metal hybrid bonded to the first chip bonding pads 38, and the second chip bonding pads 45 and one or more of the remaining interposer bonding pads 27 metal-metal hybrid bonded to the second chip bonding pads 45. The bonding insulating layer 50 may include, for example, a silicon nitride (SiN), a silicon oxide (SiO₂), a silicon carbonitride (SiCN), or a combination thereof.

In one or more examples, an underfill material layer 60 may be formed between each of the plurality of first semiconductor devices 30 and the interposer substrate 20 and between the second semiconductor device 40 and the interposer substrate 20. In one or more examples, the underfill material layer 60 may be an epoxy material that fills gaps between a chip and its carrier or a finished package and the PCB substrate. The underfill material layer 60 may protect electronic products from shock, drop, and vibration and reduces the strain on fragile solder connections caused by the difference in thermal expansion between the silicon chip and carrier. The underfill material layer 60 may fill the space between each of the plurality of first semiconductor devices 30 and the interposer substrate 20 and the space between the second semiconductor device 40 and the interposer substrate 20. The underfill material layer 60 may be made of, for example, epoxy resin. The underfill material layer 60 may include a portion of a second molding layer 70 formed in a molded underfill (MUF) method, for example.

In one or more examples, the second molding layer 70 may be disposed on the package substrate 10. The second molding layer 70 may surround side faces of each of the plurality of first semiconductor devices 30, the interposer substrate 20, and the second semiconductor device 40. The second molding layer 70 may include, for example, an epoxy molding compound. The second molding layer 70 may be formed separately from the first molding layer 37. In one or more embodiments, the second molding layer 70 may not cover an upper face of the uppermost first semiconductor device 30. In other embodiments, the second molding layer 70 may also cover the upper face of the uppermost first semiconductor device 30. In one or more examples, the first molding layer 37 and the second molding layer 70 may be formed of the same material. In one or more examples, the first molding layer 37 and the second molding layer 70 may be formed of different materials.

The semiconductor package 100 of the embodiments may include the bridge chip 25 that is arranged in the interposer substrate 20 and includes the memory controller and the input/output circuit. In one or more examples, the first semiconductor device 30 and the second semiconductor device 40 that constitute the semiconductor package 100 may be metal-metal hybrid bonded to the bridge chip 25. Since the memory controller and the input/output circuit, which are not implemented as fine circuits, are formed in the bridge chip 25 arranged in the interposer substrate 20 instead of in a process unit (e.g., the second semiconductor device 40), the process unit implemented as a fine circuit may be manufactured relatively inexpensively. In this regard, since the memory controller and input/output circuit are removed from a fine circuit such as the semiconductor device 40, and included in the bridge chip, which is not a fine circuit, the semiconductor chip 40 may be manufactured at a lower cost. Furthermore, since a fine circuit may be formed in the area of the process unit not occupied by the memory controller and the input/output circuit, the performance of the process unit may be improved as well.

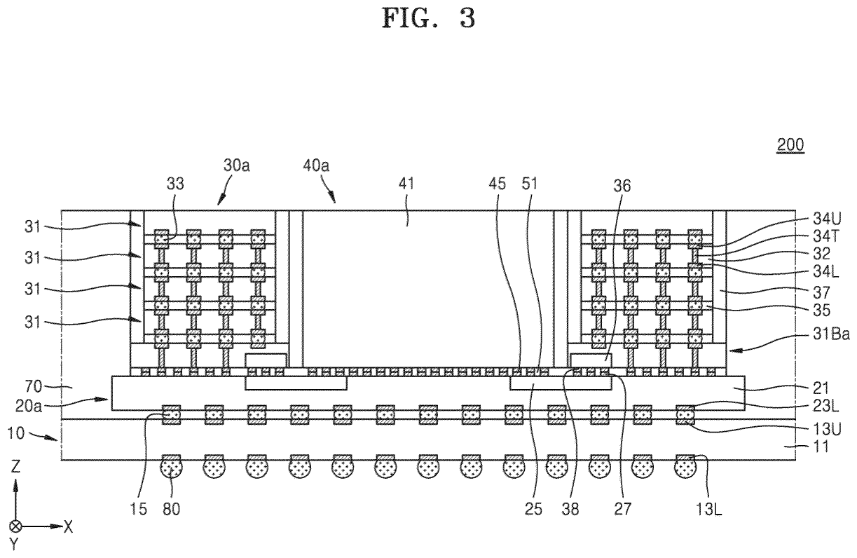

FIG. 3 is a cross-sectional view illustrating a semiconductor package 200 according to embodiments. Since each component of the semiconductor package 200 illustrated in FIG. 3 is similar to each component of the semiconductor package 100 described with reference to FIGS. 1 and 2, the following description is made focusing on the differences.

Referring to FIG. 3, the semiconductor package 200 may have a generally similar construction to the semiconductor package 100 described with reference to FIGS. 1 and 2, except that a first semiconductor device 30a and a second semiconductor device 40a are metal-metal hybrid bonded to an interposer substrate 20a.

In one or more examples, the semiconductor package 200 may include the first semiconductor device 30a including a first semiconductor chip 31Ba having a lower face on which a first chip bonding pad 38 is formed, the second semiconductor device 40a having a lower face on which a second chip bonding pad 45 is formed, and the interposer substrate 20a having an upper face on which an interposer bonding pad 27 is formed. For example, compared to the semiconductor package 100 in FIG. 2, the lower pad 34L may not be formed on the lower face of the first semiconductor chip 31Ba of the first semiconductor device 30a, the second chip pad 43 (see FIG. 2) may not be formed on the lower face of the second semiconductor device 40a, and the upper pad 23U (see FIG. 2) may not be formed on the upper face of the interposer substrate 20a. The first semiconductor device 30a may be bonded to the interposer substrate 20a by metal-metal hybrid bonding between the first chip bonding pad 38 and the interposer bonding pad 27, and the second semiconductor device 40a may be bonded to the interposer substrate 20a by metal-metal hybrid bonding between the second chip bonding pad 45 and the interposer bonding pad 27.

In one or more examples, a bonding insulating layer 51 may be arranged between the first semiconductor device 30a and the interposer substrate 20a and between the second semiconductor device 40a and the interposer substrate 20a. The bonding insulating layer 51 may surround the first chip bonding pads 38 and some of the interposer bonding pads 27 metal-metal hybrid bonded to the first chip bonding pads 38, and the second chip bonding pads 45 and some of the remaining interposer bonding pads 27 metal-metal hybrid bonded to the second chip bonding pads 45. The bonding insulating layer 51 may include, for example, a silicon nitride (SiN), a silicon oxide (SiO₂), a silicon carbonitride (SiCN), or a combination thereof.

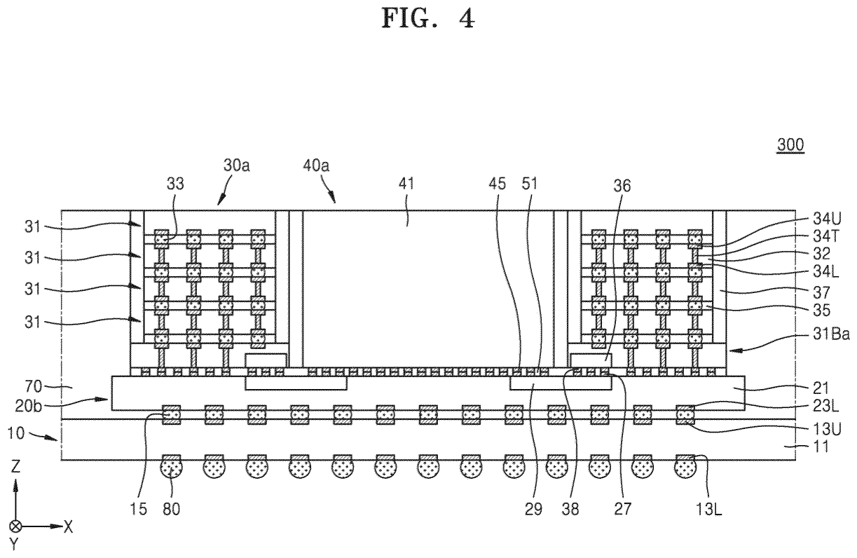

FIG. 4 is a cross-sectional view illustrating a semiconductor package 300 according to embodiments. Since each component of the semiconductor package 300 illustrated in FIG. 4 is similar to each component of the semiconductor package 200 described with reference to FIG. 3, the following description is made focusing on the differences.

Referring to FIG. 4, the semiconductor package 300 may have a generally similar construction to the semiconductor package 200 described with reference to FIG. 3 except that a circuit structure 29 is formed in an interposer substrate 20b.

The semiconductor package 300 may include the interposer substrate 20b in which the circuit structure 29 is formed. The circuit structure 29 may be electrically connected to the first semiconductor device 30a and the second semiconductor device 40a through the interposer bonding pad 27. The circuit structure 29 may be formed in the interposer substrate 20b during the manufacturing process of the interposer substrate 20b. For example, as described below, the bridge chip 25 of the semiconductor package 100 illustrated in FIGS. 1 and 2 and the bridge chip 25 of the semiconductor package 200 illustrated in FIG. 3 are separate chips mounted in the interposer substrate 20, whereas the circuit structure 29 of the semiconductor package 300 illustrated in FIG. 4 may form a portion of the interposer substrate 20b. The circuit structure 29 may include, for example, a memory controller and an input/output circuit.

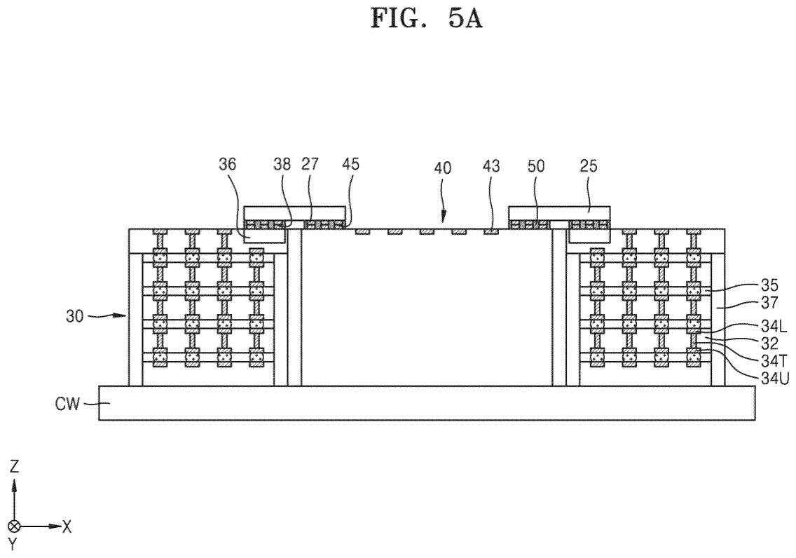

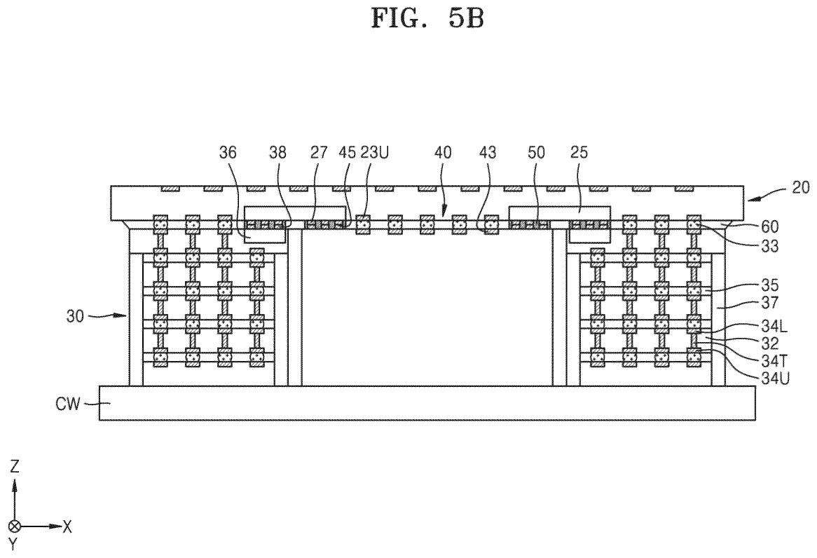

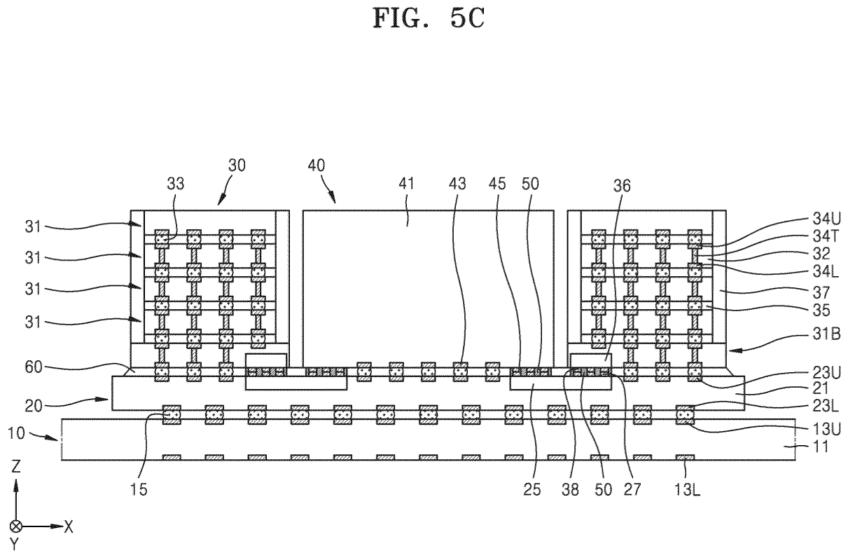

FIGS. 5A, 5B, and 5C are cross-sectional views illustrating a method of manufacturing the semiconductor package 100, according to embodiments.

Referring first to FIG. 5A, the first semiconductor device 30 including the first chip bonding pad 38 and the second semiconductor device 40 including the second chip bonding pad 45 may be provided on a support substrate CW. The support substrate CW may include, for example, a silicon substrate or a glass substrate. The construction of each of the first semiconductor device 30 and the second semiconductor device 40 has been described in detail with reference to FIGS. 1 and 2 and is therefore omitted below.

In one or more examples, the bridge chip 25 on which the interposer bonding pad 27 is formed such that the interposer bonding pad 27 overlaps the first chip bonding pad 38 in a vertical direction (Z direction) and the interposer bonding pad 27 overlaps the second chip bonding pad 45 in the vertical direction (Z direction) may be provided on the first semiconductor device 30 and the second semiconductor device 40. The bridge chip 25 may be provided on the first semiconductor device 30 and the second semiconductor device 40 such that the interposer bonding pad 27 faces the first chip bonding pad 38 and the second chip bonding pad 45. The bridge chip 25 may include, for example, a memory controller and an input/output circuit.

In one or more examples, the interposer bonding pad 27 may be metal-metal hybrid bonded to the first chip bonding pad 38 and the interposer bonding pad 27 may be metal-metal hybrid bonded to the second chip bonding pad 45 by heat and pressure, respectively. By the metal-metal hybrid bonding, the bridge chip 25 may be electrically connected to the first semiconductor device 30 and the second semiconductor device 40.

Referring to FIG. 5B, in the result of FIG. 5A, the interposer substrate 20 having a space in which the bridge chip 25 may be mounted may be provided. In the space, the bridge chip 25 may be mounted in the interposer substrate 20. The interposer substrate 20 may be provided on the first semiconductor device 30 and the second semiconductor device 40 such that each upper pad 23U overlaps a corresponding lower pad 34L of the first semiconductor device 30 and the second chip pad 43 of the second semiconductor device 40 in the vertical direction (Z direction). In one or more examples, the first connection terminal 33 may be formed on the upper pad 23U of the provided interposer substrate 20.

In one or more examples, the interposer substrate 20 may be connected to the first semiconductor device 30 and the second semiconductor device 40 through the first connection terminal 33. In one or more examples, the underfill material layer 60 filling between the interposer substrate 20 and the first semiconductor device 30 and between the interposer substrate 20 and the second semiconductor device 40 may be formed.

Referring to FIG. 5C, in the result of FIG. 5B, the connection terminal 15 may be formed on the lower pad 23L of the interposer substrate 20 and thereafter, the support substrate CW may be removed.

In one or more examples, the interposer substrate 20 may be provided on the package substrate 10 such that the lower pad 23L of the interposer substrate 20 overlaps the upper pad 13U of the package substrate 10 in the vertical direction (Z direction).

In one or more examples, the interposer substrate 20 may be connected to the package substrate 10 through the connection terminal 15.

In one or more examples, in the result of FIG. 5C, the second molding layer 70 that is disposed on the package substrate 10 and surrounds side faces of each of the interposer substrate 20, the first semiconductor device 30, and the second semiconductor device 40 may be formed, whereby the semiconductor package 100 illustrated in FIGS. 1 and 2 may be manufactured.

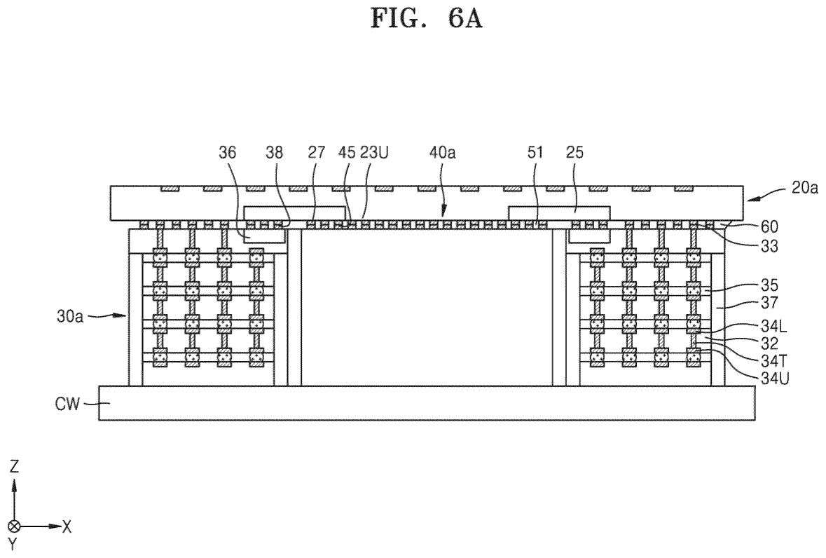

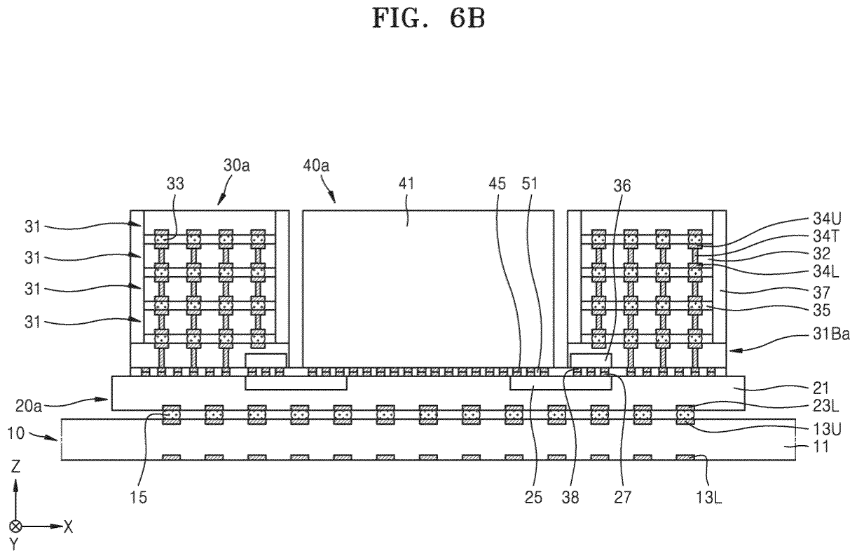

FIGS. 6A and 6B are cross-sectional views illustrating a method of manufacturing the semiconductor package 200, according to embodiments.

Referring to FIG. 6A, the first semiconductor device 30a including the first chip bonding pad 38 and the second semiconductor device 40a including the second chip bonding pad 45 may be provided on a support substrate CW. The construction of each of the first semiconductor device 30a and the second semiconductor device 40a has been described in detail with reference to FIG. 3 and is therefore omitted below.

In one or more examples, the interposer substrate 20a in which the bridge chip 25 including the memory controller and the input/output circuit is mounted may be provided on the first semiconductor device 30a and the second semiconductor device 40a. The bridge chip 25 may be manufactured separately from the interposer substrate 20a and be mounted in the interposer substrate 20a. The interposer substrate 20a may be provided on the first semiconductor device 30a and the second semiconductor device 40a and overlap each of the first chip bonding pad 38 of the first semiconductor device 30a and the second chip bonding pad 45 of the second semiconductor device 40a in a vertical direction (Z direction).

In one or more examples, the interposer bonding pad 27 may be metal-metal hybrid bonded to the first chip bonding pad 38 and the interposer bonding pad 27 may be metal-metal hybrid bonded to the second chip bonding pad 45 by heat and pressure, respectively. By the metal-metal hybrid bonding, the interposer substrate 20a may be electrically connected to the first semiconductor device 30a and the second semiconductor device 40a, and the bridge chip 25 may also be connected to the first semiconductor device 30a and the second semiconductor device 40a.

Referring to FIG. 6B, in the result of FIG. 6A, the connection terminal 15 may be formed on the lower pad 23L of the interposer substrate 20a and thereafter, the support substrate CW may be removed.

In one or more examples, the interposer substrate 20a may be provided on the package substrate 10 such that the lower pad 23L of the interposer substrate 20a overlaps the upper pad 13U of the package substrate 10 in the vertical direction (Z direction).

In one or more examples, the interposer substrate 20a may be connected to the package substrate 10 through the connection terminal 15.

In one or more examples, in the result of FIG. 6B, the second molding layer 70 that is disposed on the package substrate 10 and surrounds side faces of each of the interposer substrate 20a, the first semiconductor device 30a, and the second semiconductor device 40a may be formed, whereby the semiconductor package 200 illustrated in FIG. 3 may be manufactured.

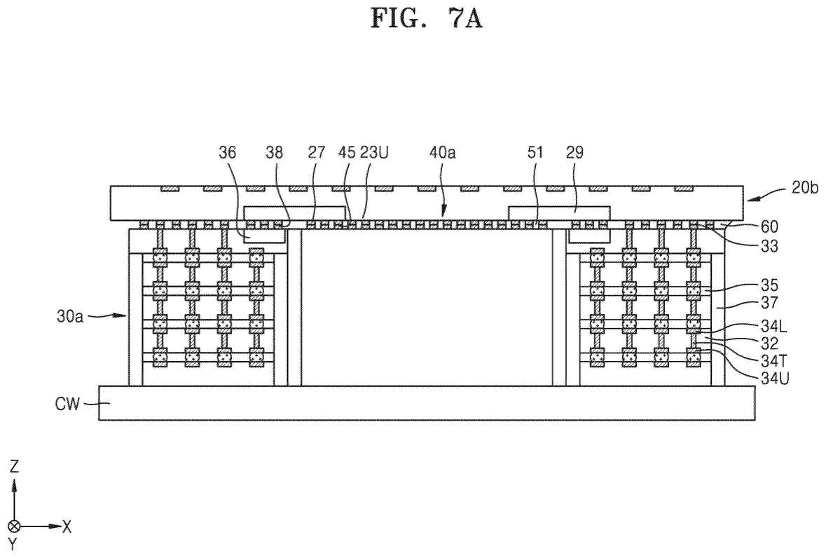

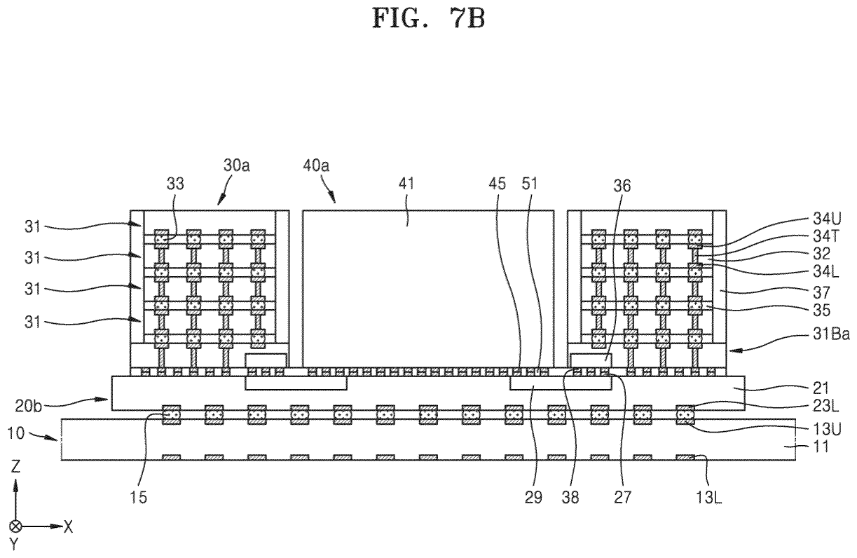

FIGS. 7A and 7B are cross-sectional views illustrating a method of manufacturing the semiconductor package 300, according to embodiments.

Referring to FIG. 7A, the first semiconductor device 30a including the first chip bonding pad 38 and the second semiconductor device 40a including the second chip bonding pad 45 may be provided on a support substrate CW. The construction of each of the first semiconductor device 30a and the second semiconductor device 40a has been described in detail with reference to FIG. 4 and is therefore omitted below.

In one or more examples, the interposer substrate 20b in which the circuit structure 29 including the memory controller and the input/output circuit is formed may be provided on the first semiconductor device 30a and the second semiconductor device 40a. The interposer substrate 20b may be provided on the first semiconductor device 30a and the second semiconductor device 40a such that the interposer bonding pad 27 overlaps each of the first chip bonding pad 38 of the first semiconductor device 30a and the second chip bonding pad 45 of the second semiconductor device 40a in the vertical direction (Z direction).

In one or more examples, the interposer bonding pad 27 may be metal-metal hybrid bonded to the first chip bonding pad 38 and the interposer bonding pad 27 may be metal-metal hybrid bonded to the second chip bonding pad 45 by heat and pressure, respectively. By the metal-metal hybrid bonding, the interposer substrate 20b may be electrically connected to the first semiconductor device 30a and the second semiconductor device 40a, and the circuit structure 29 formed in the interposer substrate 20b may also be electrically connected to the first semiconductor device 30a and the second semiconductor device 40a.

Referring to FIG. 7B, in the result of FIG. 7A, the connection terminal 15 may be formed on the lower pad 23L of the interposer substrate 20b and thereafter, the support substrate CW may be removed.

In one or more examples, the interposer substrate 20b may be provided on the package substrate 10 such that the lower pad 23L of the interposer substrate 20b overlaps the upper pad 13U of the package substrate 10 in the vertical direction (Z direction).

In one or more examples, the interposer substrate 20b may be connected to the package substrate 10 through the connection terminal 15.

In one or more examples, in the result of FIG. 7B, the second molding layer 70 that is disposed on the package substrate 10 and surrounds side faces of each of the interposer substrate 20b, the first semiconductor device 30a, and the second semiconductor device 40a may be formed, whereby the semiconductor package 300 illustrated in FIG. 3 may be manufactured.

As described above, the embodiments have been disclosed in the drawings and specification. In this specification, the embodiments have been described using specific terms, but this is only used for the purpose of explaining the technical idea of the embodiments of the present disclosure and is not used to limit the meaning or scope of the embodiments of the present disclosure described in the claims. Therefore, those skilled in the art will understand that various modifications and other equivalent embodiments are possible therefrom. Therefore, the true technical protection scope of the embodiments of the present disclosure should be defined by the technical spirit of the attached claims.

While the embodiments of the present disclosure has been particularly shown and described with reference to embodiments thereof, it will be understood that various changes in form and details may be made therein without departing from the spirit and scope of the following claims.

What is claimed is:

1. A semiconductor package comprising:
an interposer substrate in which a bridge chip is mounted;
a first semiconductor device on the interposer substrate, the first semiconductor device comprising a first semiconductor chip and a plurality of second semiconductor chips that are sequentially stacked in a first direction; and
a second semiconductor device spaced apart from the first semiconductor device in a second direction perpendicular to the first direction,
wherein an interposer bonding pad is on a face of the bridge chip, a first chip bonding pad that overlaps at least part of the interposer bonding pad in the first direction is on a face of the first semiconductor chip, and a second chip bonding pad that overlaps part of a remaining interposer bonding pad in the first direction except the part of the interposer bonding pad that overlaps the first chip bonding pad in the first direction is on a face of the second semiconductor device, and
wherein the interposer bonding pad is metal-metal hybrid bonded to the first chip bonding pad and the second chip bonding pad.

2. The semiconductor package of claim 1,
wherein the bridge chip comprises a memory controller and an input/output circuit, and the memory controller and the input/output circuit are each connected to the first semiconductor device and the second semiconductor device.

3. The semiconductor package of claim 1,
wherein the interposer bonding pad has a pitch of about 1 nm to about 9 nm.

4. The semiconductor package of claim 1,
wherein a pad is on a portion of the face of the first semiconductor chip that does not overlap the bridge chip in the first direction among the face of the first semiconductor chip, a pad is on a portion of the face of the second semiconductor device that does not overlap the bridge chip in the first direction among the face of the second semiconductor device, and the pad of the first semiconductor chip and the pad of the second semiconductor device are each connected to a pad of the interposer substrate by a connection terminal.

5. The semiconductor package of claim 4,
wherein the connection terminal comprises a solder ball or a bump.

6. The semiconductor package of claim 4,
wherein the first chip bonding pad, the second chip bonding pad, and the interposer bonding pad are surrounded by a bonding insulating layer, and the bonding insulating layer is surrounded by an underfill material layer located between the first semiconductor device and the interposer substrate and between the second semiconductor device and the interposer substrate.

7. The semiconductor package of claim 1,
wherein the first chip bonding pad is on a portion of the face of the first semiconductor chip that does not overlap the bridge chip in the first direction, the second chip bonding pad is on a portion of the face of the second semiconductor device that does not overlap the bridge chip in the first direction and does not overlap the bridge chip, and the interposer bonding pad is on a portion of a face of the interposer substrate that does not overlap the bridge chip in the first direction, and
wherein the first chip bonding pad and the second chip bonding pad are each metal-metal hybrid bonded to the interposer bonding pad.

8. The semiconductor package of claim 7,
wherein a bonding insulating layer that surrounds the first chip bonding pad, the second chip bonding pad, and the interposer bonding pad is located between the first semiconductor device and the interposer substrate and between the second semiconductor device and the interposer substrate.

9. A semiconductor package comprising:
an interposer substrate comprising a circuit structure;
a first semiconductor device on the interposer substrate, the first semiconductor device comprising a first semiconductor chip and a plurality of second semiconductor chips that are sequentially stacked in a first direction; and
a second semiconductor device spaced apart from the first semiconductor device in a second direction perpendicular to the first direction,
wherein an interposer bonding pad is on a portion of a face of the interposer substrate that overlaps the circuit structure in the first direction, a first chip bonding pad that overlaps at least part of the interposer bonding pad in the first direction is on a face of the first semiconductor chip, and a second chip bonding pad that overlaps part of a remaining interposer bonding pad in the first direction except the part of the interposer bonding pad that overlaps the first chip bonding pad in the first direction is on a face of the second semiconductor device, and
wherein the interposer bonding pad is metal-metal hybrid bonded to the first chip bonding pad and the second chip bonding pad.

10. The semiconductor package of claim 9,
wherein the circuit structure comprises a memory controller and an input/output circuit, and the memory controller and the input/output circuit are each connected to the first semiconductor device and the second semiconductor device.

11. The semiconductor package of claim 9,
wherein the circuit structure is formed together with the interposer substrate.

12. The semiconductor package of claim 9,
wherein the interposer bonding pad has a pitch of about 1 nm to about 9 nm.

13. The semiconductor package of claim 9,
wherein the second semiconductor device does not comprise a memory controller and does not comprise an input/output circuit.

14. The semiconductor package of claim 9,
wherein the first chip bonding pad is on a portion of the face of the first semiconductor chip that does not overlap the circuit structure in the first direction, the second chip bonding pad is on a portion of the face of the second semiconductor device that does not overlap the circuit structure in the first direction, and the interposer bonding pad is on a portion of the face of the interposer substrate that does not overlap the circuit structure in the first direction, and
the first chip bonding pad and the second chip bonding pad are each metal-metal hybrid bonded to the interposer bonding pad.

15. The semiconductor package of claim 9,
wherein a bonding insulating layer that surrounds the first chip bonding pad, the second chip bonding pad, and the interposer bonding pad is located between the first semiconductor device and the interposer substrate and between the second semiconductor device and the interposer substrate.

16. A semiconductor package comprising:
a package substrate;
an interposer substrate on the package substrate and in which a bridge chip is mounted;
a first semiconductor device on the interposer substrate, the first semiconductor device comprising a first semiconductor chip and a plurality of second semiconductor chips that are sequentially stacked in a first direction; and
a second semiconductor device spaced apart from the first semiconductor device in a second direction perpendicular to the first direction,
wherein an interposer bonding pad is on a face of the bridge chip, a first chip bonding pad that overlaps at least part of the interposer bonding pad in the first direction is on a face of the first semiconductor chip, and a second chip bonding pad that overlaps part of a remaining interposer bonding pad in the first direction except the part of the interposer bonding pad that overlaps the first chip bonding pad in the first direction is on a face of the second semiconductor device, and
the interposer bonding pad is metal-metal hybrid bonded to the first chip bonding pad and the second chip bonding pad.

17. The semiconductor package of claim 16,
wherein the bridge chip comprises a memory controller and an input/output circuit, and the memory controller and the input/output circuit are each connected to the first semiconductor device and the second semiconductor device.

18. The semiconductor package of claim 16,
wherein a pad is on a portion of the face of the first semiconductor chip that does not overlap the bridge chip in the first direction, a pad is on a portion of the face of the second semiconductor device that does not overlap the bridge chip in the first direction, the pad on the first semiconductor chip and the pad on the second semiconductor device are each connected to a pad on the interposer substrate by a connection terminal, and the connection terminal comprises a solder ball or a bump.

19. The semiconductor package of claim 16,
wherein the first chip bonding pad, the second chip bonding pad, and the interposer bonding pad are surrounded by a bonding insulating layer, and the bonding insulating layer is surrounded by an underfill material layer that is located between the first semiconductor device and the interposer substrate and between the second semiconductor device and the interposer substrate.

20. The semiconductor package of claim 19, further comprising:
a molding layer on the package substrate and surrounding side faces of each of the interposer substrate, the first semiconductor device, and the second semiconductor device, wherein the molding layer contacts the underfill material layer.
